(19) United States
(12) Patent Application Publication
(10) Pub. No.: US 2007/0240300 A1
(43) Pub. Date: Oct. 18, 2007

(54) Method for manufacturing electrode, apparatus for manufacturing electrode, and method for manufacturing secondary cell

(75) Inventor: Hironori Hasei, Okaya-shi (JP)

Correspondence Address: GLOBAL IP COUNSELORS, LLP, 1233 20TH STREET, NW, SUITE 700, WASHINGTON, DC, 20036-2680, US

(73) Assignee: Seiko Epson Corporation, Shinjuku-ku (JP)

(21) Appl. No.: 11/783,045

(22) Filed: Apr. 5, 2007

(30) Foreign Application Priority Data
Apr. 12, 2006 (JP) JP 2006-109463

(51) Int. Cl. H01M 10/04; B05D 5/12; B05D 3/02; C23C 14/00

(52) U.S. Cl. 29/623.5; 427/58; 427/372.2; 427/126.3; 118/50

(57) ABSTRACT

A method for manufacturing an electrode having a collector and an electrode layer containing an active material formed on the collector is provided that includes the steps of discharging a composition for forming an electrode layer containing an active material and an organic solvent on the collector from a droplet discharge apparatus to form a film composed of the composition, reducing the pressure of an atmosphere surrounding the film within a prescribed period of time to a pressure that brings a boiling point of the organic solvent to a temperature in a range of 10° C. to 30° C., and maintaining the reduced pressure to dry and remove the organic solvent to form the electrode layer. The method can further include the step of heating the film to a temperature between 50° C. and 150° C., after the reduced pressure is maintained.

### CROSS-REFERENCE TO RELATED APPLICATIONS

This application claims priority to Japanese Patent Application No. 2006-109463 filed on Apr. 12, 2006. The entire disclosure of Japanese Patent Application No. 2006-109463 is hereby incorporated herein by reference.

### BACKGROUND

1. Technical Field

The present invention relates to a method for manufacturing an electrode using a droplet discharge apparatus, an apparatus for manufacturing an electrode, and a method for manufacturing a secondary cell.

2. Related Art

In recent years, electric vehicles (EV), hybrid vehicles (HEV), and fuel cell vehicles (FCV) have come to be used in commercial applications, and the development of cells as a power source for these vehicles is being carried out at a high pitch. There is a demand for cells that are capable of repeated charging and discharging, that have high output and high energy density, and that satisfy other very rigorous requirements.

In Japanese Laid-Open Patent Application Publication No. 2003-151526, which is designed to satisfy these requirements, a cell is proposed in which plate-shaped positive and negative electrodes are accommodated in an enclosure, a liquid electrolyte is sealed in the container to form a thin secondary cell, and several of these secondary cells are connected in a series-parallel configuration.

A known method for manufacturing the positive and negative electrodes of such thin secondary cell involves coating electrode material (positive electrode material or negative electrode material) onto a collector by using a coating apparatus referred to as a “coater,” and forming an electrode. With this method, however, coating nonuniformities tend to be generated, and it is difficult to rigorously control the thickness of the electrode layer and to manufacture a cell provided with uniform charging and discharging characteristics.

Japanese Laid-Open Patent Application Publication No. 2005-11656 and Japanese Laid-Open Patent Application Publication No. 2005-11657 propose, as means of solving these problems, methods for forming a thin electrode layer by discharging a solution (composition for forming an electrode layer) containing an active material and an organic solvent on the surface of a substrate by using an inkjet droplet discharge apparatus, and heating the resulting coated film by using a heating plate or the like.

Nevertheless, a problem with using an inkjet droplet discharge apparatus is that the composition for forming an electrode is applied in droplets. Therefore, convection currents are produced within the film, and the solute becomes unbalanced in the heating and drying steps due the use of an oven or hot plate, drying nonuniformities are generated in the surface of the electrode layer thus formed, and a uniform electrode layer cannot be obtained.

The present invention was contrived in view of the foregoing state of the prior art. This invention addresses this need in the art as well as other needs, which will become apparent to those skilled in the art from this disclosure.

### SUMMARY

One advantage of the present invention is to provide a method for manufacturing an electrode that does not have drying nonuniformities and has a thin, uniform electrode layer; to provide an apparatus for manufacturing an electrode; and to provide a method for manufacturing a secondary cell.

The present inventors, as a result of thoroughgoing research to solve the above-described problems, perfected the present invention having discovered that an electrode that does not have drying nonuniformities and has a uniform electrode layer can be formed by discharging a composition for forming an electrode layer containing an active material and an organic solvent from a droplet discharge apparatus onto a collector to form a film composed of the composition; reducing in a prescribed period of time after film formation the pressure of an atmosphere surrounding the film to a prescribed pressure; and drying and removing the solvent by maintaining the reduced pressure.

Thus, in accordance with the first aspect of the present invention, methods for manufacturing an electrode are provided in (1) to (5) below.

(1) A method for manufacturing an electrode having a collector and an electrode layer containing an active material formed on the collector, the method comprising discharging a composition for forming an electrode layer containing an active material and an organic solvent on the collector from a droplet discharge apparatus to form a film composed of the composition; reducing the pressure of an atmosphere surrounding the film within a prescribed period of time to a pressure that brings the boiling point of the organic solvent to a temperature in a range of 10° C. to 30° C.; and maintaining the reduced pressure to dry off the solvent and to form an electrode layer.

(2) A method for manufacturing an electrode having a collector and an electrode layer containing an active material formed on the collector, the method comprising discharging a composition for forming an electrode layer containing an active material and an organic solvent on the collector from a droplet discharge apparatus to form a film composed of the composition; reducing the pressure of an atmosphere surrounding the film in a prescribed period of time to a pressure that brings the boiling point of the organic solvent to a temperature in a range of 10° C. to 30° C.; and maintaining the reduced pressure and further heating the film to a temperature in a range of 50° C. to 150° C. to dry off the solvent and to form an electrode layer.

(3) The method for manufacturing an electrode according to the method (1) or (2), wherein the electrode is a positive electrode of a secondary cell.

(4) The method for manufacturing an electrode according to any of the methods (1) to (3), wherein the electrode layer is formed having an average film thickness in a range of 0.1 μm to 50 μm.

(5) The method for manufacturing an electrode according to the method (4), wherein the active material is a positive active material that contains at least one of an Li—Mn-based complex oxide and an Li—Co-based complex oxide.

In accordance with the method for manufacturing an electrode of the present invention, an electrode layer that does not have drying nonuniformities and has a uniform thickness can be formed. Therefore, the electrode obtained by the manufacturing method of the present invention can be advantageously used in large-capacity secondary cells that have uniform charging and discharging characteristics.

In accordance with the second aspect of the present invention, an apparatus for manufacturing an electrode is provided in (6) to (8) below.

(6) An apparatus for manufacturing an electrode having a collector and an electrode layer containing an active material formed on the collector, the apparatus comprising a droplet discharge apparatus configured and arranged to discharge a composition for forming an electrode layer containing an active material and an organic solvent on the collector to form a film composed of the composition; and a decompression and drying apparatus configured and arranged to reduce the pressure of an atmosphere surrounding the film in a prescribed period of time to a pressure that brings the boiling point of the organic solvent to a temperature in a range of 10° C. to 30° C., and to maintain the reduced pressure to dry off the solvent and to form an electrode layer.

(7) The apparatus for manufacturing an electrode according to the apparatus (6), wherein the decompression and drying means further has a function for heating the film to a temperature in a range of 50° C. to 150° C.

(8) The apparatus for manufacturing an electrode according to the apparatus (6) or (7), being an apparatus for manufacturing a positive electrode for a secondary cell.

In accordance with the apparatus for manufacturing an electrode of the present invention, an electrode layer that does not have drying nonuniformities and has a uniform thickness can be formed with good efficiency.

The apparatus for manufacturing an electrode of the present invention can be advantageously used in the method for manufacturing an electrode of the present invention.

In accordance with the third aspect of the present invention, methods for manufacturing a secondary cell are provided in (9) and (10) below.

(9) A method for manufacturing a secondary cell having a negative electrode, an electrolyte, and a positive electrode, the method comprising discharging a composition for forming an electrode layer containing an active material and an organic solvent on the collector from a droplet discharge apparatus to form a film composed of the composition; reducing the pressure of an atmosphere surrounding the film in a prescribed period of time to a pressure that brings the boiling point of the organic solvent to a temperature in a range of 10° C. to 30° C.; maintaining the reduced pressure to dry off the solvent and to form an electrode layer; and forming a positive electrode or a negative electrode.

(10) A method for manufacturing a secondary cell having a negative electrode, an electrolyte, and a positive electrode, the method comprising discharging a composition for forming an electrode layer containing an active material and an organic solvent on the collector from a droplet discharge apparatus to form a film composed of the composition; reducing the pressure of an atmosphere surrounding the film in a prescribed period of time to a pressure that brings the boiling point of the organic solvent to a temperature in a range of 10° C. to 30° C.; maintaining the reduced pressure and further heating to a temperature in a range of 50° C. to 150° C. to dry off the solvent and to form an electrode layer; and forming one of the positive electrode and the negative electrode.

In accordance with the method for manufacturing a secondary cell of the present invention, a step is provided for forming an electrode layer that does not have drying nonuniformities and has a uniform thickness. Therefore, a secondary cell can be obtained in which the heat dissipation is uniform, local degradation does not easily occur, and cracks and disconnections are not likely to occur.

These and other objects, features, aspects and advantages of the present invention will become apparent to those skilled in the art from the following detailed description, which, taken in conjunction with the annexed drawings, discloses a preferred embodiment of the present invention.

### BRIEF DESCRIPTION OF THE DRAWINGS

Referring now to the attached drawings which form a part of this original disclosure:

FIG. 1 is an overall schematic diagram showing an example of the manufacturing line of a secondary cell according to an embodiment of the present invention;

FIG. 2 is a simplified schematic diagram showing an example of the droplet discharge apparatus used in the present invention;

FIG. 3 is a simplified schematic diagram showing an example of the decompression apparatus used in the present invention; and

FIG. 4 is a simplified structural cross-sectional view of the lithium cell according to an embodiment of the present invention.

### DESCRIPTION OF EXEMPLARY EMBODIMENTS

Selected embodiment of the present invention will now be explained with reference to the drawings. It will be apparent to those skilled in the art from this disclosure that the following description of the embodiment of the present invention is provided for illustration only and not for the purpose of limiting the invention as defined by the appended claims and their equivalents.

### (1) Method and Apparatus for Manufacturing Electrode

The method for manufacturing an electrode of the present invention is a method for manufacturing an electrode having a collector and an electrode layer containing an active material formed on the collector, comprising discharging a composition for forming an electrode layer containing an active material and an organic solvent (may hereinafter be simply referred to as “composition”) from a droplet discharge apparatus to form a film composed of the composition; reducing in a prescribed period of time the pressure of an atmosphere surrounding the film to a pressure that brings the boiling point of the organic solvent to 10° C. to 30° C.; and maintaining the reduced pressure to dry off the solvent and to form an electrode layer.

The collector used in the present invention is not particularly limited as long as the material is in the form of a sheet comprising electroconductive material, examples of which include aluminum, copper, nickel, and stainless steel that have been worked into the form of a metal foil, electrolytic foil, rolled foil, embossed article, foam sheet, or the like.

The thickness of the collector is not particularly limited and is ordinarily 5 μm to 30 μm.

The composition used in the present invention contains an active material and an organic solvent. The composition used in the present invention contains a positive electrode active material when a positive electrode layer is to be formed, and contains a negative electrode active material when a negative electrode layer is to be formed.

The positive electrode active material is not particularly limited, and any known positive electrode active material can be used. Examples of materials that may be used when a positive electrode for a lithium cell is to be formed include LiMn₂O₄ and other Li—Mn-based complex oxides; LiCoO₂ and other Li—Co-based complex oxides; and LiNiO₂ and other Li—Ni-based complex oxides. These positive electrode active materials may be used alone or in a combination of two or more.

The negative electrode active material is not particularly limited, and any known negative electrode active material can be used. Examples of materials that may be used when a negative electrode for a lithium cell is to be formed include lithium, titanium, other metals, and alloys of these metals; and natural graphite, artificial graphite, carbon black, active carbon, carbon fiber, coke, soft carbon, hard carbon, graphite, and other carbon materials. These negative electrode active materials may be used alone or in a combination of two or more.

The organic solvent used in the composition is not particularly limited, but from the standpoint of operating efficiency, the organic solvent preferably has a boiling point in a range of 50° C. to 200° C. at normal pressure. Examples of such an organic solvent include N-methylpyrrolidone, N,N-dimethylformamide, N,N-dimethylacetamide, and other amide-based solvents; acetonitrile, propionitrile, and other nitrile-based solvents; tetrahydrofuran, 1,2-dimethoxy ethane, diisopropyl ether, and other ether-based solvents; acetone, methylethyl ketone, diethyl ketone, methyl isobutyl ketone, cyclohexanone, and other ketone-based solvents; ethyl acetate, propyl acetate, methyl lactate, and other ester solvents; benzene, toluene, xylene, chlorobenzene, and other aromatic solvents; chloroform, 1,2-dichloro ethane, and other halide solvents; and mixed solvents composed of two or more of these solvents.

The composition may contain other components as required. Examples of other components include polyvinylidene fluoride and other binding agents; carbon black, acetylene black, Ketjen black, graphite, and other electroconductive materials.

The composition may be prepared by mixing/stirring the active material and other components as required in the organic solvent. The method of mixing and stirring is not particularly limited, and conventionally known mixers/stirrers may be used.

The blending ratio of the active material, other components, and organic solvent in the composition is not particularly limited. The blending amount of active material is ordinarily 10 wt % to 60 wt % with respect to the entire composition. The blending amount of other components is ordinarily 0 wt % to 20 wt % with respect to the entire composition. The blending amount of organic solvent is ordinarily 20 wt % to 90 wt % with respect to the entire composition.

The viscosity of the composition is not particularly limited, but is preferably low enough to allow droplets to be discharged. The viscosity of the composition is preferably about 1 to 100 cP. Examples of methods for adjusting the viscosity of the composition to achieve this range include methods that vary (increase or otherwise modify) the blending ratio of the organic solvent, methods that increase the temperature of the composition, and methods that add polyelectrolyte starting materials and other compounds to the composition so that the viscosity is reduced.

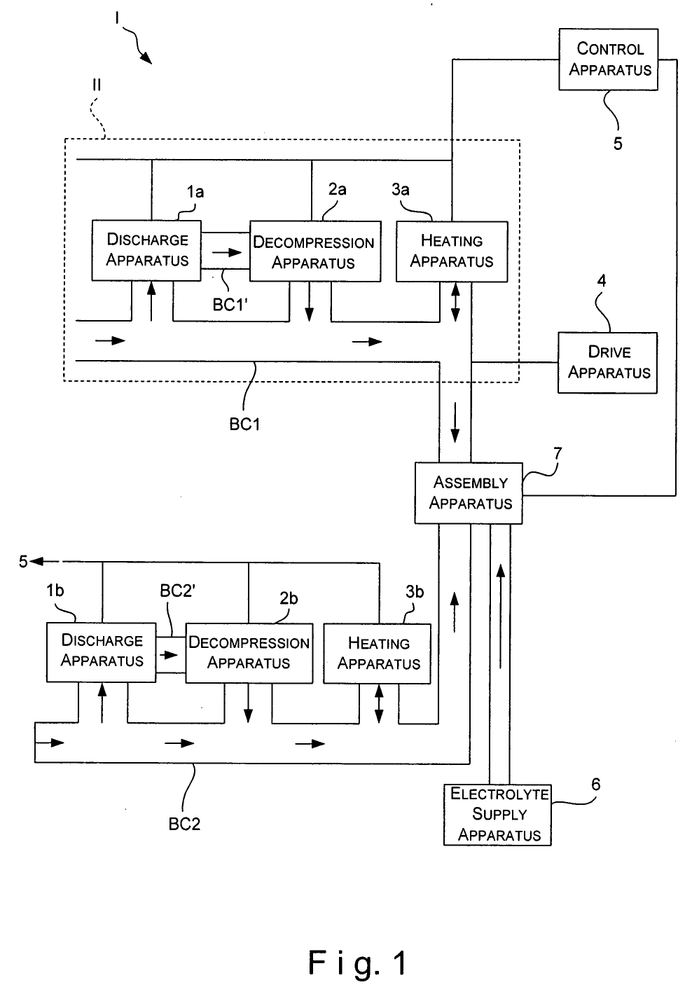

The method for manufacturing the electrode of the present invention can be implemented using the electrode manufacturing line II within the dotted line in the manufacturing line I of the secondary cell in FIG. 1, for example.

The electrode manufacturing line II in FIG. 1 is composed of a droplet discharge apparatus 1a (hereinafter referred to as “discharge apparatus 1a”), a decompression apparatus 2a, a heating apparatus 3a, a belt conveyor BC1 for connecting the appratuses, and a belt conveyor BC1′. These apparatuses are connected to a drive apparatus 4 that drives the belt conveyor BC1 and other belt conveyors, and to a control apparatus 5 for controlling all of the apparatuses.

First, aluminum foil or another metal foil having a desired size is prepared, and the composition for forming an electrode layer prepared in the manner described above is discharged from the discharge apparatus la to form a film composed of the composition.

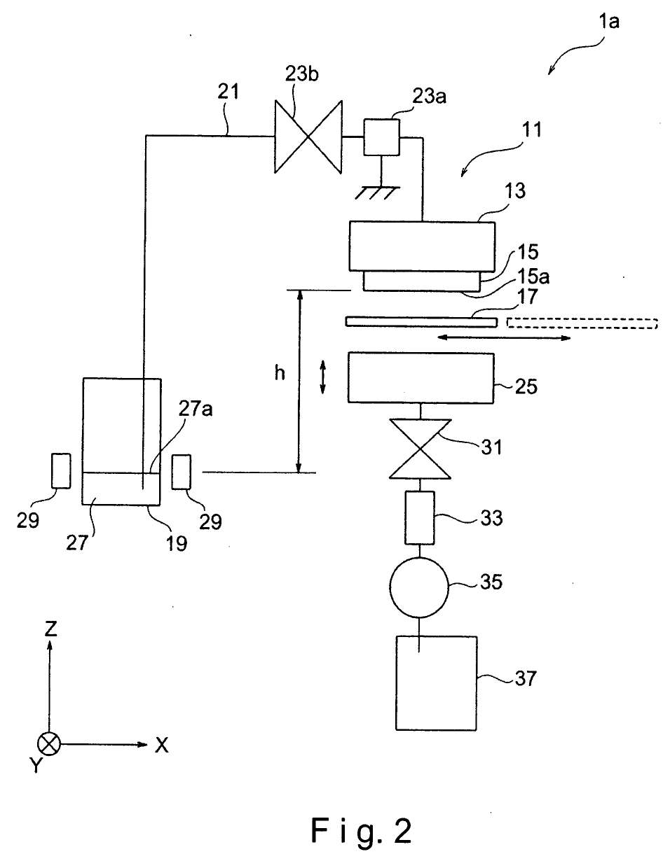

FIG. 2 shows an example of the droplet discharge apparatus used in the present invention. FIG. 2 is a diagram showing a schematic of the configuration of the inkjet discharge apparatus 1a.

The discharge apparatus 1a is not particularly limited as long as the apparatus is a so-called inkjet discharge apparatus. Examples include thermal discharge apparatuses that discharge droplets by generating foam using thermal foaming to discharge the droplets, and piezo-type discharge apparatuses that discharge droplets using the compression of a piezo element.

The discharge apparatus 1a is provided with an inkjet head 11 that discharges a discharge substance (composition for forming an electrode layer) onto the collector. The inkjet head 11 is provided with a head main body 13 and a nozzle formation surface 15 on which numerous nozzles are formed for discharging the discharge substance. The discharge substance is discharged from the nozzles of the nozzle formation surface 15 onto the collector.

The discharge apparatus 1a is provided with a table 17 on which the collector is placed. The table 17 is disposed so as to be capable of movement in prescribed directions, e.g., the X-axis direction, Y-axis direction, and Z-axis direction. The collector transported on the belt conveyor BC1 is placed on the table 17, and the table 17 is moved in the direction along the X axis, as indicated by the arrow in the diagram, and is taken into the discharge apparatus 1a.

A tank 19 containing the discharge substance that is to be discharged from the nozzles formed in the nozzle formation surface 15 is connected to the inkjet head 11. Specifically, the tank 19 and inkjet head 11 are connected by a discharge substance transport tube 21 for transporting the discharge substance.

The discharge substance transport tube 21 is provided with a discharge substance flow channel ground coupling 23a and a head unit foam scavenging valve 23b for preventing the inside of the flow channel of the discharge substance transport tube 21 from becoming electrified. The head unit foam scavenging valve 23b is used when the discharge substance inside the inkjet head 11 is suctioned by a later-described suction cap 25. Specifically, when the discharge substance inside the inkjet head 11 is suctioned by the suction cap 25, the head unit foam scavenging valve 23b is closed, and the discharge substance is prevented from flowing from the tank 19. When the discharge substance is suctioned by the suction cap 25, the flow rate of the suctioned discharge substance increases, and the foam inside the inkjet head 11 is rapidly drawn out.

The discharge apparatus 1a is provided with a liquid surface control sensor 29 for controlling the amount of discharge substance stored in the tank 19, i.e., the height of liquid surface 27a of the discharge substance stored in the tank 19. The liquid surface control sensor 29 keeps the difference h (hereinafter referred to as “water head value”) between the liquid surface 27a inside the tank 19 and the distal end 15a of the nozzle formation surface 15 provided to the nozzle formation surface 15 within a prescribed range. The discharge substance 27 inside the tank 19 is fed to the inkjet head 11 using a pressure in a prescribed range by controlling the height of the liquid surface 27a. The discharge substance 27 can be stably discharged from the inkjet head 11 by sending the discharge substance 27 using a pressure within a prescribed range.

A flow channel is disposed below the suction cap 25, and a suction valve 31, a suction pressure detection sensor 33 for sensing suction abnormalities, and a suction pump 35 composed of a tube pump or the like are disposed in the flow channel. The discharge substance suctioned by the suction pump 35 and other components and transported through the flow channel is stored in a waste fluid tank 37.

The volume of the droplets of the discharge substance discharged from the discharge apparatus is preferably in a range of 1 to 100 pL. When the volume of the discharged droplets is too low, vibration reduction tends to be insufficient. When the volume of the droplets is too high, vibration reduction tends to be insufficient as well. Since the volume of the particles to be discharged using the discharge apparatus is substantially the same, the resulting electrode layer has excellent uniformity.

In the present invention, a film composed of the composition is formed on the collector, and the pressure of the atmosphere surrounding the film is then reduced in a prescribed period of time to a pressure that brings the boiling point of the organic solvent to a temperature in a range of 10° C. to 30° C. Specifically, in FIG. 1, the collector (may hereinafter be referred to as a “collector having a film”) on which the composition film has been formed is transported into a decompression apparatus 2a by way of the belt conveyor BC1′, the operation for reducing the pressure so as to bring the boiling point of the organic solvent contained in the composition to a temperature in a range of 10° C. to 30° C. is carried out within a prescribed period of time, and this state is maintained, whereby the organic solvent is dried and removed.

The prescribed period of time is not particularly limited, but is preferably as short a period of time as physically possible, and is specifically 30 seconds to several minutes.

The level of decompression is a pressure that will bring the boiling point of the organic solvent used in the composition to a temperature in a range of 10° C. to 30° C., and preferably in a range of 15° C. to 25° C. When, for example, N-methylpyrrolidone is used as the organic solvent, the pressure that will bring the boiling point of N-methylpyrrolidone to 15° C. to 25° C. is about 50 Pa. Therefore, the level of decompression in the decompression apparatus 2a must be 50 Pa.

After the prescribed level decompression has been reached in the decompression apparatus 2a, the time for maintaining the decompression level is not particularly limited as long as the time is sufficient for drying and removing the solvent contained in the composition. This length of time is ordinarily 10 seconds to 10 minutes, and is preferably 30 seconds to 3 minutes.

In this manner, the organic solvent can be rapidly removed without moving the liquid in the film coated using the inkjet method by adopting a method for drying and removing the organic solvent contained in the composition. As a result, an electrode layer without drying nonuniformities can be formed.

The decompression apparatus used in the present invention is not particularly limited as long as the decompression level in the space containing the collector having a film is a level that brings the boiling point of the organic solvent to a temperature in a range of 10° C. to 30° C., and the decompression level can be maintained for a sufficient length of time to dry and remove the organic solvent contained in the composition.

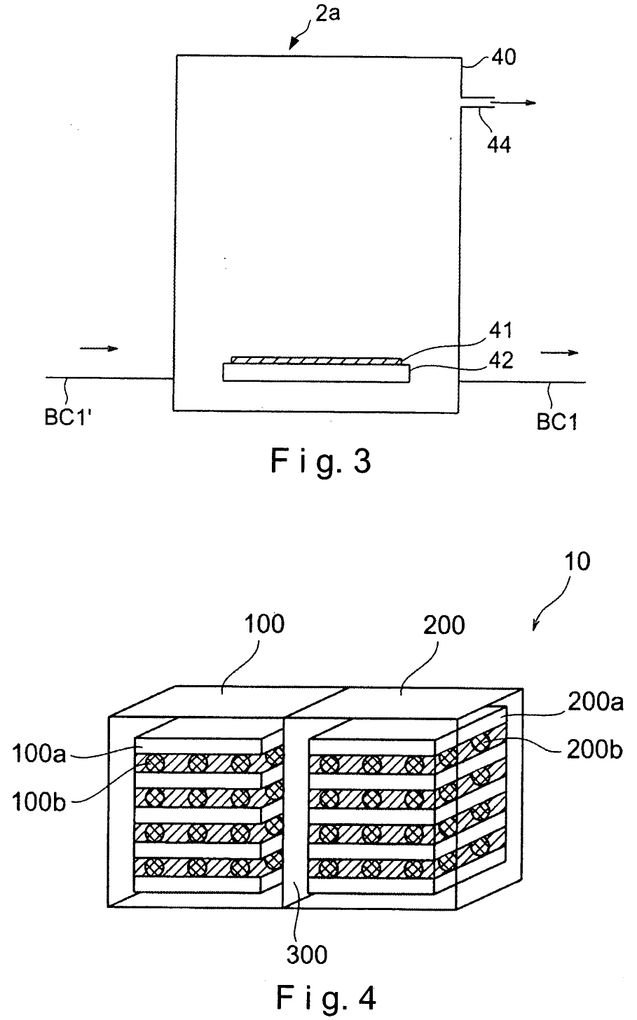

FIG. 3 shows a schematic diagram of an example of the decompression apparatus 2a used in the present invention. The decompression apparatus 2a shown in FIG. 3 has a chamber 40 that accommodates a collector 41 having a film, a table 42 on which the collector 41 having a film is placed, and a ventilation port 44 for suctioning and exhausting air that is present inside the chamber 40 to the exterior. The table 42 is connected to the belt conveyor BC1′ (BC1) that transports the collector 41 having a film in and out of the chamber. The ventilation port 44 is connected to a decompression pump, which is not shown in the diagram.

The collector 41 having a film is transported into the decompression apparatus 2a by way of the belt conveyor BC1′ and is then immediately sealed inside the chamber 40. The interior of the chamber 40 is rapidly decompressed and brought to a prescribed decompression level. As described above, after the film has been formed, the time required to bring the interior of the chamber 40 to a prescribed decompression level is 30 seconds to no more than several minutes, and is preferably 30 seconds to no more than 1 minute.

Although not shown, the entire discharge apparatus 1a may be accommodated inside the chamber 40 of the decompression apparatus 2a. By adopting such a configuration, the interior of the chamber can be rapidly decompressed immediately after the film has been formed. The pressure is reduced in a state in which the collector having a film is placed on the table of the droplet discharge apparatus, and the collector having a film can be brought into prescribed decompressed atmosphere in a shorter period of time without being transported from the droplet discharge apparatus to the decompression apparatus. In this case, however, a cover must be placed on the discharge nozzle head of the drop discharge apparatus, or some other step must be taken because the entire droplet discharge apparatus will be placed in the decompressed atmosphere.

In the present invention, the collector having a film is preferably heated and dried at a temperature in a range of 50° C. to 150° C. after the compression drying has been carried out. The drying and removal of the organic solvent can be completed by heating and drying.

The drying and heating can, for example, be carried out by transporting the collector having a film in the decompression apparatus 2a into the heating apparatus 3a by way of the belt conveyor BC1, as shown in FIG. 1, and heating the collector having a film to a temperature in a range of 50° C. to 150° C.

The heating time depends on the heating temperature and is ordinarily 30 seconds to 1 hour.

The heating method may be a method that uses a hot plate, an oven, or the like.

The heating and drying may be carried out in the decompression apparatus chamber by disposing heating means in the decompression apparatus. When, for example, a hot plate function is provided to the table 42 on which the collector having a film is placed inside the decompression apparatus 2a, the heating and drying can be performed inside the decompression apparatus chamber without transporting the collector from the decompression apparatus to a heating apparatus.

The heating and drying may carried out under decompression or at normal pressure. Heating may, for example, be carried out after decompression drying by using the decompression apparatus 2a while maintaining the decompression level, or the heating may be carried out after the pressure inside the chamber 40 has be returned to normal pressure.

An electrode having a collector and an electrode layer can be manufactured in the manner described above. The surface of the resulting electrode layer is uniform without drying nonuniformities. It is possible to visually observe that the surface does not have nonuniformities.

The average thickness of the electrode layer is not particularly limited, but a thickness in a range of 0.1 μm to 50 μm is preferred.

The average thickness of the electrode in which an electrode layer has been formed on a collector is preferably in a range of 10 μm to 70 μm. The thickness of the electrode and cell can be measured using a known micrometer.

The thickness of the electrode layer to be formed may be adjusted using the number of times that the same discharge pattern is overwritten. When, for example, a film and an electrode layer having insufficient thickness are formed by discharging droplets of the composition a single time, droplets can be discharged twice in the same location to increase the thickness of the electrode layer.

The electrode manufactured in accordance with the present invention has an average thickness, but since it is very flat and devoid of nonuniformities, a cell manufactured using this electrode can have a long life without being cracked or broken by the resonance caused by nonuniformities in the electrode.

The electrode manufactured in accordance with the present invention can be used as an electrode for various types of cells. Among these, the electrode is preferably the positive electrode of a secondary cell because the effects of the electrode can be more effectively applied, and the electrode is preferably the positive electrode of a lithium ion secondary cell.

### (2) Method for Manufacturing Secondary Cell

The method for manufacturing a secondary cell of the present invention is a method for manufacturing a secondary cell having a negative electrode, an electrolyte, and a positive electrode, comprising the steps of discharging a composition for forming an electrode layer containing an active material and an organic solvent from a droplet discharge apparatus to form a film composed of the composition; reducing in a prescribed period of time the pressure of an atmosphere surrounding the film to a pressure that brings the boiling point of the organic solvent to a temperature in a range of 10° C. to 30° C.; maintaining the reduced pressure to dry off the solvent and to form an electrode layer; and forming a positive electrode or a negative electrode.

A secondary cell is composed of a positive electrode, an electrolyte, and a negative electrode arranged in the stated order, and these are sealed in an enclosure. Specifically, the positive and negative electrodes are manufactured, an electrolyte is disposed between the resulting positive and negative electrodes, and these components are sealed in an enclosure, whereby a secondary cell can be assembled.

The method for manufacturing a secondary cell of the present invention can be implemented by using the electrode manufacturing line I for a secondary cell shown in FIG. 1.

In the manufacturing line I, a positive electrode is manufactured using the above-described electrode manufacturing line II inside in the broken line. In a parallel process, a negative electrode is formed in the same manner as in the method for manufacturing the positive electrode by using a manufacturing line for manufacturing a negative electrode composed of a discharge apparatus 1b, a decompression apparatus 2b, a heating apparatus 3b, a belt conveyor BC2, and a belt conveyor BC2′. The resulting positive and negative electrodes are accommodated in an enclosure in an assembly apparatus 7, and the electrolyte is supplied to and sealed inside the assembly by using an electrolyte supply apparatus 6, whereby a secondary cell can be manufactured.

Examples of the electrolyte include, LiClO₄, LiPF₆, LiBF₄, LiAsF₆, LiSbF₆, LiCF₃SO₃, LiC₄F₉SO₃, LiCF₃CO₂, Li₂C₂F₄(SO₃)₂, LiN(CF₃SO₂)₂, LiCₙF₂ₙ₊₁SO₃ (n≧2), LIN(RfOSO₂)₂ (wherein Rf is a fluoroalkyl group), LiN(CF₃SO₂)(C₄F₉SO₂), LiN(C₂F₅SO₂)(C₄F₉SO₂), LiN(CF₃SO₂)(C₂F₅SO₂); a macromer of ethylene oxide and propylene oxide; gel polymer electrolytes, true polymer electrolytes, LiPON, and other inorganic solid electrolytes comprising various polymers; and Li ion-containing salts dissolving at normal temperature.

When the electrolyte contains a solvent, the solvent may be, e.g., 1,2-dimethoxyethane, 1,2-diethoxyethene, propylene carbonate, ethylene carbonate, ν-butyrolactone, tetrahydrofuran, 1,3-dioxolane, diethyl carbonate, dimethyl carbonate, or ethyl methyl carbonate. These may be used alone or in a plural combination.

A separator is preferably disposed between the positive and negative electrodes in order to electrically insulate the electrodes, as shown in FIG. 4, for example.

The cell 10 shown in FIG. 4 is a layered lithium cell in which a positive electrode 100 and a negative electrode 200 are partitioned by a separator 300. In FIG. 4, the positive electrode 100 has a structure in which a collector 100a and a positive electrode layer 100b are layered in series, and the negative electrode 200 has a structure in which a collector 200a and a negative electrode layer 200b are layered in series. An electrolyte that is not shown in the diagram is filled into the interior of the positive and negative electrodes.

In the lithium cell shown in FIG. 4, LiCoO₂, for example, is used as the positive electrode active material, and carbon (C) is used as the negative electrode active material. Charging and discharging can be repeated as shown below.

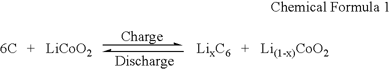

In the above chemical formula 1, the value x is a positive number that is less than 1.

The separator is not particularly limited as long as the separator can withstand the service range of the secondary cell. Examples include polyethylene, polypropylene, and other olefin-based resins; copolymers of polypropylene, polyethylene, and the like; and other fine porous films. These films may be used alone or in combination.

The thickness of the separator is not particularly limited, but the thickness is ordinarily 10 μm to 50 μm.

The enclosure is not particularly limited, and an example is a polymer metal composite film or the like in which at least a metal foil film and a resin film are layered.

In the industrial production process for a secondary cell, a step may be adopted in which an electrode that is larger than the ultimate size of the cell may be fabricated and cut into prescribed size in order to improve productivity.

The shape of the secondary cell may be a stacked, cylindrical, flat, or another shape. A stacked secondary cell, for example, can be manufactured by cutting the positive and negative electrodes manufactured in the manner described above into suitable sizes, mounting terminals, holding the electrolyte material between the two electrodes under a dry argon atmosphere, and vacuum sealing the assembly inside an aluminum stack in a state in which the terminals have been brought out to the exterior.

A cylindrical secondary cell can be manufactured, for example, by layering the positive electrode, separator, negative electrode, separator in sequence in a winding fashion using the positive and negative electrodes manufactured in the manner described above, cutting the cell at a prescribed length, inserting the cell in a cylindrical iron can, adding an electrolyte, and sealing the can.

The cell manufactured in accordance with the present invention is particularly useful when used in vehicles that require high output, high energy density, and other rigorous conditions. The resulting cell has high durability in relation to vibrations, and cell degradation due to resonance does not easily occur even when used in vehicles and other environments in which vibrations are always present.

### WORKING EXAMPLE

The present invention is described in further detail below using examples. However, the present invention is not limited in any way by these examples.

### Example 1

A spinel LiMn₂O₄ (average particle size: 0.6 μm) (20 mass %) as the positive electrode active material, carbon black (2 parts by mass) as the electroconductive material, and a surfactant (5 parts by mass) for stabilizing the dispersion of the solid content were prepared, and N-methylpyrrolidone (75 parts by mass) was added to the above. The components were sufficiently stirred and the composition for forming a positive electrode layer (hereinafter referred to as “composition 1”) was prepared. The viscosity of the composition was 10 cP.

Using the composition 1, a positive electrode layer was formed in the following manner using the electrode manufacturing line II shown in FIG. 1.

The composition 1 was introduced to the discharge apparatus 1a, and the composition was discharged onto aluminum foil having a thickness of 20 μm as a collector to form a film of the composition 1.

The collector on which the film had been formed was transported within 1 minute after film formation from the discharge apparatus 1a into a decompression apparatus 2a having heating means. The interior of the chamber of the decompression apparatus 2a was decompressed to 50 Pa, which is a pressure that brings the boiling point of N-methylpyrrolidone to about 20° C. The same pressure was maintained for 1 minute, and the interior of the chamber was then returned to normal pressure. The collector having a film was heated and dried for 30 minutes at 120° C. by using a hot plate, and a positive electrode layer was formed.

The average thickness of the resulting positive electrode layer was measured and found to be 2 μm. The average thickness was measured using a micrometer (manufactured by Sigma Koki Co.).

The surface of the resulting positive electrode layer was observed for drying nonuniformities. As a result, no drying nonuniformities were generated.

### Comparative Example 1

A composition 1 was prepared in the same manner as example 1, and a film was formed on a collector. The collector on which the film had been formed was left standing for 5 minutes after the film had been formed, was thereafter placed on a hot plate heated to 120° C., and was heated and dried for 30 minutes

The average thickness of the resulting positive electrode layer was measured, and since the unbalance in the thickness of the film was very high, calculated was not possible.

The resulting positive electrode layer was visually observed for drying nonuniformities on the surface of the positive electrode layer. Drying nonuniformities were present and the electrode layer had partially peeled away.

### General Interpretation of Terms

In understanding the scope of the present invention, the term “configured” as used herein to describe a component, section or part of a device includes hardware and/or software that is constructed and/or programmed to carry out the desired function. In understanding the scope of the present invention, the term “comprising” and its derivatives, as used herein, are intended to be open ended terms that specify the presence of the stated features, elements, components, groups, integers, and/or steps, but do not exclude the presence of other unstated features, elements, components, groups, integers and/or steps. The foregoing also applies to words having similar meanings such as the terms, “including”, “having” and their derivatives. Also, the terms “part,” “section,” “portion,” “member” or “element” when used in the singular can have the dual meaning of a single part or a plurality of parts. Finally, terms of degree such as “substantially”, “about” and “approximately” as used herein mean a reasonable amount of deviation of the modified term such that the end result is not significantly changed. For example, these terms can be construed as including a deviation of at least +5% of the modified term if this deviation would not negate the meaning of the word it modifies.

While only selected embodiments have been chosen to illustrate the present invention, it will be apparent to those skilled in the art from this disclosure that various changes and modifications can be made herein without departing from the scope of the invention as defined in the appended claims. Furthermore, the foregoing descriptions of the embodiments according to the present invention are provided for illustration only, and not for the purpose of limiting the invention as defined by the appended claims and their equivalents.

1. A method for manufacturing an electrode having a collector and an electrode layer containing an active material formed on the collector, the method comprising:
discharging a composition for forming an electrode layer containing an active material and an organic solvent on the collector from a droplet discharge apparatus to form a film composed of the composition;
reducing the pressure of an atmosphere surrounding the film within a prescribed period of time to a pressure that brings a boiling point of the organic solvent to a temperature in a range of 10° C. to 30° C.; and
maintaining the reduced pressure to dry and remove the organic solvent to form the electrode layer.

2. A method for manufacturing an electrode having a collector and an electrode layer containing an active material formed on the collector, the method comprising:
discharging a composition for forming an electrode layer containing an active material and an organic solvent on the collector from a droplet discharge apparatus to form a film composed of the composition;
reducing the pressure of an atmosphere surrounding the film within a prescribed period of time to a pressure that brings a boiling point of the organic solvent to a temperature in a range of 10° C. to 30° C.;
maintaining the reduced pressure; and
heating the film to a temperature between 50° C. and 150° C., after the maintaining of the reduced pressure, to dry and remove the organic solvent to form an electrode layer.

3. The method for manufacturing an electrode according to claim 1, wherein
the electrode layer is a positive electrode of a secondary cell.

4. The method for manufacturing an electrode according to claim 1, wherein
the film forms the electrode layer having an average film thickness in a range of 0.1 μm to 50 μm.

5. The method for manufacturing an electrode according to claim 4, wherein
the active material is a positive active material that contains at least one of an Li—Mn-based complex oxide and an Li—Co-based complex oxide.

6. An apparatus for manufacturing an electrode having a collector and an electrode layer containing an active material formed on the collector, the apparatus comprising:
a droplet discharge apparatus configured and arranged to discharge a composition for forming an electrode layer containing an active material and an organic solvent on the collector to form a film composed of the composition; and
a decompression and drying apparatus configured and arranged to reduce the pressure of an atmosphere surrounding the film to a pressure that brings a boiling point of the organic solvent to a temperature in a range of 10° C. to 30° C. within a prescribed period of time, and to maintain the reduced pressure to dry and remove the solvent to form the electrode layer.

7. The apparatus for manufacturing an electrode according to claim 6, wherein
the decompression and drying apparatus is further configured and arranged to heat the film to a temperature in a range or 50° C. to 150° C.

8. The apparatus for manufacturing an electrode according to claim 6, wherein
the electrode layer is a positive electrode of a secondary cell.

9. A method for manufacturing a secondary cell having a negative electrode, an electrolyte, and a positive electrode, the method comprising:
discharging a composition for forming an electrode layer containing an active material and an organic solvent on a collector from a droplet discharge apparatus to form a film composed of the composition;
reducing the pressure of an atmosphere surrounding the film within a prescribed period of time to a pressure that brings a boiling point of the organic solvent to a temperature in a range of 10° C. to 30° C.; and
maintaining the reduced pressure to dry and remove the organic solvent to form one of the negative electrode and the positive electrode of the secondary cell.

10. A method for manufacturing a secondary cell having a negative electrode, an electrolyte, and a positive electrode, the method comprising:
discharging a composition for forming an electrode layer containing an active material and an organic solvent on the collector from a droplet discharge apparatus to form a film composed of the composition;
reducing the pressure of an atmosphere surrounding the film within a prescribed period of time to a pressure that brings a boiling point of the organic solvent to a temperature in a range of 10° C. to 30° C.;
maintaining the reduced pressure; and
heating the film to a temperature between 50° C. and 150° C., after the maintaining of the reduced pressure, to dry and remove the organic solvent to form one of the negative electrode and the positive electrode of the secondary cell.

11. The method for manufacturing an electrode according to claim 2, wherein
the electrode layer is a positive electrode of a secondary cell.

12. The method for manufacturing an electrode according to claim 2, wherein
the film forms the electrode layer having an average film thickness in a range of 0.1 μm to 50 μm.

13. The method for manufacturing an electrode according to claim 3, wherein
the film forms the electrode layer having an average film thickness in a range of 0.1 μm to 50 μm.

14. The method for manufacturing an electrode according to claim 11, wherein
the film forms the electrode layer having an average film thickness in a range of 0.1 μm to 50 μm.

15. The apparatus for manufacturing an electrode according to claim 7, wherein
the electrode layer is a positive electrode of a secondary cell.
